(19) United States
(12) Patent Application Publication
(10) Pub. No.: US 2023/0005745 A1
(43) Pub. Date: Jan. 5, 2023

(54) Forming Method for Semiconductor Layer

(71) Applicant: Nippon Telegraph and Telephone Corporation, Tokyo (JP)

(72) Inventors: Ryo Nakao, Musashino-shi, Tokyo (JP); Tomonari Sato, Musashino-shi, Tokyo (JP)

(21) Appl. No.: 17/779,268

(22) PCT Filed: Dec. 3, 2019
(86) PCT No.: PCT/JP2019/047223

§ 371 Date: May 24, 2022

(51) Int. Cl. H01L 21/02; C30B 25/12

(52) U.S. Cl. CPC H01L 21/02694; C30B 25/12

(57) ABSTRACT

A recess and a recess are formed at places where a threading dislocation and a threading dislocation reach a surface of a third semiconductor layer. A through-hole and a through-hole are formed in a second semiconductor layer under places of the recess and the recess, the through-hole and the through-hole extending through the second semiconductor layer. A first semiconductor layer is oxidized through the recess, the recess, the through-hole, and the through-hole to form an insulation film that covers a lower surface of the second semiconductor layer. The third semiconductor layer is subjected to crystal regrowth.

### TECHNICAL FIELD

The present invention relates to a method of forming semiconductor layers, and to a method of forming semiconductor layers obtained by forming semiconductors through crystal growth on a substrate, the semiconductors being different in lattice constant from the substrate.

### BACKGROUND ART

Semiconductor thin films are used as the material of electronic devices or optical devices. Many of semiconductors utilized for devices have a layered structure, and are formed through crystal growth on a substrate made of a semiconductor, sapphire, or the like using a crystal growth device. Although crystal growth has been performed to achieve lattice matching with the substrate, lattice mismatched growth (heteroepitaxial growth) such as crystal growth of GaN on a sapphire substrate and crystal growth of a compound semiconductor on a Si substrate have come to be performed for the purpose of mass production and improvement of device properties.

In heteroepitaxial growth, any type of crystal defects is introduced into a heterointerface, and this extends through into a layer (device layer) constituting a semiconductor electronic/optical device. Since this threading defect degrades device properties, it is important to prevent the threading defect (threading dislocation density). Some technologies for reducing the threading dislocation density have been proposed so far, and include, for example, epitaxial lateral overgrowth (ELO), aspect ratio trapping (ART), confined epitaxial lateral overgrowth (CELO), a dislocation filter using strained layer superlattice (SLS), and the like.

In ELO described in Non-Patent Literature 1, for example, a material such as SiO₂ is deposited on a semiconductor substrate to be subjected to heteroepitaxial growth to form a mask. This mask is partly provided with an opening, and crystal growth is performed from a surface of the semiconductor substrate exposed at the bottom surface of this opening. In this crystal growth, use of growth conditions for growing semiconductor crystals so as to cover the mask around the opening in addition to a place directly above the mask opening enables propagation of dislocations from the substrate to be prevented in semiconductor layers formed on the mask. However, it is difficult for ELO, which is free from the effect of preventing propagation of dislocations in the mask opening, to reduce the dislocation density in the grown semiconductor layers over the whole region in a planar direction of a substrate. In addition, lateral crystal growth over the mask around the opening is more difficult than typical growth in the direction vertical to the plane of the substrate, and the shape of the mask and the shape of the opening as seen in plan view are restricted. Thus, there arise problems in that, for example, a necessary semiconductor device structure cannot necessarily be produced in semiconductor layers formed on the mask.

Next, ART described in Non-Patent Literature 2 will be described. ART is a method of forming a mask including an opening of a stripe structure whose ratio (aspect ratio) of thickness to length (width) in the planar direction is increased, and selectively performing crystal growth on the surface of the substrate at the place of the opening, thereby terminating dislocations in the inner wall of the opening. However, propagation of dislocations cannot be prevented in the direction in which stripes extend because of the absence of the inner wall, although the effect of preventing propagation of dislocations is exerted in a direction orthogonal to the direction in which the stripes extend. In addition, growth with increased aspect ratio raises problems in that a region that enables growth is reduced, and a grown surface is not flat.

Next, CELO described in Non-Patent Literature 3 will be described. CELO is a method of forming thin channels in a surface of a substrate by processing an insulation film formed on the substrate, and supplying raw materials and performing growth through the channels to significantly reduce the dislocation density. In this CELO, however, production of a channel structure is complicated, and a region that enables growth is extremely small. In addition, in CELO, growth needs to be performed on a crystal surface in directions other than a direction vertical to the surface of the substrate, which makes the growth itself difficult.

Next, SLS described in Non-Patent Literature 4 will be described. SLS uses a dislocation filter. This dislocation filter is easy to produce, and thus, SLS has already been widely used. On the other hand, SLS is less effective in reducing the dislocation density, and forms no layer made of an insulation material. Thus, it is not always possible to prevent dislocations from rising from the substrate side toward layers in which devices are formed after producing a device structure.

### CITATION LIST

### Non-Patent Literature

Non-Patent Literature 1: H. Kataria et al., “Simple Epitaxial Lateral Overgrowth Process as a Strategy for Photonic Integration on Silicon”, IEEE Journal of Selected Topics in Quantum Electronics, vol. 20, no. 4, 8201407, 2014.
Non-Patent Literature 2: J. G. Fiorenza et al., “Aspect Ratio Trapping: a Unique Technology for Integrating Ge and III-Vs with Silicon CMOS”, ECS Transactions, vol. 33, no. 6, pp. 963-976, 2010.
Non-Patent Literature 3: L. Czornomaz et al., “Confined Epitaxial Lateral Overgrowth (CELO): A Novel Concept for Scalable Integration of CMOS-compatible InGaAs-on-insulator MOSFETs on Large-Area Si Substrates”, Symposium on VLSI Technology Digest of Technical Papers, 13-3, pp. T172-T173, 2015.
Non-Patent Literature 4: R. Hull. et al., “Role of strained layer superlattices in misfit dislocation reduction in growth of epitaxial Ge0.5Si0.5 alloys on Si(100) substrates”, Journal of Applied Physics, vol. 65, no. 12, pp. 4723-4729, 1989.

### SUMMARY OF THE INVENTION

### Technical Problem

As described above, various methods of reducing the dislocation density when performing heteroepitaxial growth have been proposed, but these conventional technologies raise problems in that it is neither possible to produce semiconductor layers with significantly reduced dislocation density by a simple manufacturing method, nor to prevent dislocations from rising (propagating) to a desired semiconductor layer after production.

The present invention was made to solve problems as described above, and has an object to produce semiconductor layers with reduced dislocation density by a simple production method, and to prevent occurrence of dislocations in dislocations to a desired semiconductor layer after production.

### Means for Solving the Problem

A method of forming semiconductor layers according to the present invention includes: a first step of forming a first semiconductor layer through crystal growth on a substrate, the first semiconductor layer being different from the substrate in lattice constant in a planar direction of a surface of the substrate; a second step of forming a second semiconductor layer through crystal growth on and in contact with the first semiconductor layer; a third step of forming a third semiconductor layer through crystal growth on and in contact with the second semiconductor layer; a fourth step of selectively dissolving a place of a dislocation in the third semiconductor layer using the second semiconductor layer as an etching stop layer to form a recess at the place of the dislocation, the recess extending through the third semiconductor layer; a fifth step of forming a through-hole in the second semiconductor layer under a place of the recess, the through-hole extending through the second semiconductor layer; a sixth step of oxidizing the first semiconductor layer through the recess and the through-hole in the second semiconductor layer to form an insulation film that covers a lower surface of the second semiconductor layer; and a seventh step of subjecting the third semiconductor layer to crystal regrowth after forming the insulation film.

A method of forming semiconductor layers according to the present invention includes: a first step of forming a first semiconductor layer through crystal growth on a substrate, the first semiconductor layer being different from the substrate in lattice constant in a planar direction of a surface of the substrate; a second step of forming a second semiconductor layer through crystal growth on and in contact with the first semiconductor layer; a third step of forming a third semiconductor layer through crystal growth on and in contact with the second semiconductor layer; a fourth step of forming a fourth semiconductor layer through crystal growth on and in contact with the third semiconductor layer; a fifth step of forming a fifth semiconductor layer through crystal growth on and in contact with the fourth semiconductor layer; a sixth step of dissolving a place of a dislocation in the fifth semiconductor layer to form a recess at the place of the dislocation, the recess extending through the fifth semiconductor layer; a seventh step of forming a first through-hole in the fourth semiconductor layer under a place of the recess, the first through-hole extending through the fourth semiconductor layer; an eighth step of forming a second through-hole in the third semiconductor layer under a place of the first through-hole through etching using the second semiconductor layer as an etching stop layer, the second through-hole extending through the third semiconductor layer; a ninth step of forming a third through-hole in the second semiconductor layer under a place of the second through-hole, the third through-hole extending through the second semiconductor layer; a tenth step of oxidizing the first semiconductor layer through the recess, the first through-hole, the second through-hole, and the second through-hole to form an insulation film that covers a lower surface of the second semiconductor layer; an eleventh step of removing the fifth semiconductor layer after forming the insulation film; a twelfth step of removing the fourth semiconductor layer after removing the fifth semiconductor layer; and a thirteenth step of subjecting the third semiconductor layer to crystal regrowth after removing the fourth semiconductor layer.

### Effects of the Invention

As described above, according to the present invention, a second semiconductor layer to serve as an etching stop layer is formed on a first semiconductor layer, a recess that reaches the second semiconductor layer is formed at a place of a dislocation in a third semiconductor layer formed on the second semiconductor layer, and furthermore, a through-hole is formed in the second semiconductor layer, and the first semiconductor layer is oxidized through the recess and the through-hole to form an insulation film that covers the lower surface of the second semiconductor layer. This allows semiconductor layers with reduced dislocation density to be produced by a simple production method, and allows dislocations to be prevented from rising to a desired semiconductor layer after production.

### BRIEF DESCRIPTION OF DRAWINGS

FIG. 1A is a sectional view showing a state of semiconductor layers in an intermediate step for describing a method of forming semiconductor layers according to a first embodiment of the present invention.

FIG. 1B is a sectional view showing a state of semiconductor layers in an intermediate step for describing the method of forming semiconductor layers according to the first embodiment of the present invention.

FIG. 1C is a sectional view showing a state of semiconductor layers in an intermediate step for describing the method of forming semiconductor layers according to the first embodiment of the present invention.

FIG. 1D is a sectional view showing a state of semiconductor layers in an intermediate step for describing the method of forming semiconductor layers according to the first embodiment of the present invention.

FIG. 1E is a sectional view showing a state of semiconductor layers in an intermediate step for describing the method of forming semiconductor layers according to the first embodiment of the present invention.

FIG. 1F is a sectional view showing a state of semiconductor layers in an intermediate step for describing the method of forming semiconductor layers according to the first embodiment of the present invention.

FIG. 1G is a sectional view showing a state of semiconductor layers in an intermediate step for describing the method of forming semiconductor layers according to the first embodiment of the present invention.

FIG. 2 is a property diagram showing a relation between threading dislocation density occurred in semiconductor layers formed through crystal growth of compound semiconductors different in lattice constant in a planar direction of a surface of a grown substrate and length of one side of regions having a rectangular shape as seen in plan view and including one dislocation in average.

FIG. 3A is a sectional view showing a state of semiconductor layers in an intermediate step for describing a method of forming semiconductor layers according to a second embodiment of the present invention.

FIG. 3B is a sectional view showing a state of semiconductor layers in an intermediate step for describing the method of forming semiconductor layers according to the second embodiment of the present invention.

FIG. 3C is a sectional view showing a state of semiconductor layers in an intermediate step for describing the method of forming semiconductor layers according to the second embodiment of the present invention.

FIG. 3D is a sectional view showing a state of semiconductor layers in an intermediate step for describing the method of forming semiconductor layers according to the second embodiment of the present invention.

FIG. 3E is a sectional view showing a state of semiconductor layers in an intermediate step for describing the method of forming semiconductor layers according to the second embodiment of the present invention.

FIG. 3F is a sectional view showing a state of semiconductor layers in an intermediate step for describing the method of forming semiconductor layers according to the second embodiment of the present invention.

FIG. 3G is a sectional view showing a state of semiconductor layers in an intermediate step for describing the method of forming semiconductor layers according to the second embodiment of the present invention.

FIG. 3H is a sectional view showing a state of semiconductor layers in an intermediate step for describing the method of forming semiconductor layers according to the second embodiment of the present invention.

### DESCRIPTION OF EMBODIMENTS

Hereinafter, a method of forming semiconductor layers according to embodiments of the present invention will be described.

### First Embodiment

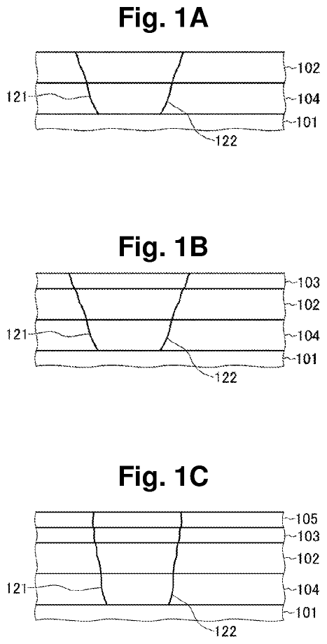

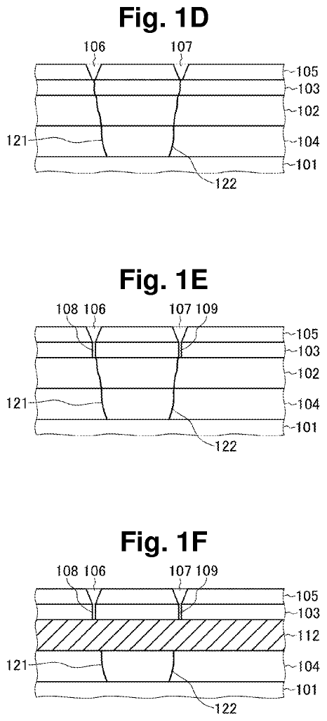

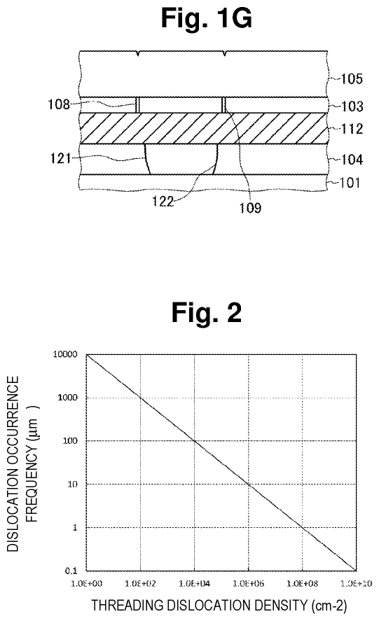

First, a method of forming semiconductor layers according to a first embodiment of the present invention will be described with reference to FIG. 1A to FIG. 1G.

First, as shown in FIG. 1A, a first semiconductor layer 102 is formed through crystal growth on a substrate 101, the first semiconductor layer 102 being different from the substrate 101 in lattice constant in a planar direction of a surface of the substrate 101 (first step). In the first embodiment, a buffer layer 104 is formed through crystal growth on the substrate 101, and the first semiconductor layer 102 is formed through crystal growth (epitaxially grown) on the buffer layer 104. The substrate 101 is composed of GaAs, for example, and the buffer layer 104 is composed of InP. Alternatively, the substrate 101 can be composed of Si.

The first semiconductor layer 102 is composed of AlAsSb. AlAsSb is a compound semiconductor containing Al. A second semiconductor layer 103 can also be composed of a compound semiconductor containing a large amount of Al, such as InAlAs. The above-described respective layers can be formed by a method such as metalorganic vapor-phase epitaxy or molecular-beam epitaxy, for example.

The buffer layer 104 composed of InP and the first semiconductor layer 102 composed of AlAsSb are different from the substrate 101 composed of GaAs in lattice constant in the planar direction of the surface of the substrate 101. This produces a threading dislocation 121 and a threading dislocation 122 at a heterointerface between the substrate 101 and the buffer layer 104 in the first embodiment. The threading dislocation 121 and the threading dislocation 122 as occurred propagate to the surface of the first semiconductor layer 102. The occurrence of the threading dislocations and propagation to the surface similarly apply to a case where the substrate 101 is composed of Si.

In such heteroepitaxial growth, a sudden, significant change in lattice constant may cause three-dimensional growth in which crystals are grown like islands or a serious damage to the crystallinity. In order to prevent such problems, the buffer layer 104 can also be composed of two layers to prevent a significant change in lattice constant, for example. Alternatively, the buffer layer 104 can also be composed of more layers to change the lattice constant in multiple stages. In other words, if the lattice constant of the buffer layer 104 in the planar direction of the surface of the substrate is changed to approach the lattice constant of the first semiconductor layer in the planar direction of the surface of the substrate toward the first semiconductor layer, the above-described problems in crystal growth can be prevented. Note that, similarly to the buffer layer 104, the lattice constant of the first semiconductor layer 102 in the planar direction of the surface of the substrate 101 can also be changed to approach the lattice constant of the first semiconductor layer 103 in the planar direction of the surface of the substrate toward the second semiconductor layer 103 which will be described later.

Next, as shown in FIG. 1B, the second semiconductor layer 103 is formed through crystal growth on and in contact with the first semiconductor layer 102 (second step). The second semiconductor layer 103 is composed of a compound semiconductor such as InGaAs, for example. The threading dislocation 121 and the threading dislocation 122 having propagated to the surface of the first semiconductor layer 102 propagate to the surface of the second semiconductor layer 103.

Next, as shown in FIG. 1C, a third semiconductor layer 105 is formed through crystal growth on and in contact with the second semiconductor layer 103 (third step). The third semiconductor layer 105 is composed of a compound semiconductor such as InP, for example. The threading dislocation 121 and the threading dislocation 122 having propagated to the surface of the second semiconductor layer 103 propagate to the surface of the third semiconductor layer 105.

Next, as shown in FIG. 1D, a recess 106 and a recess 107 are formed at places where the threading dislocation 121 and the threading dislocation 122 reach the surface of the third semiconductor layer 105, the recess 106 and the recess 107 extending through the third semiconductor layer 105 to reach the first semiconductor layer 102 (fourth step). By selectively dissolving the places of the threading dislocation 121 and the threading dislocation 122 having reached the surface of the third semiconductor layer 105, the recess 106 and the recess 107 can be formed.

For example, by etching the places of the threading dislocation 121 and the threading dislocation 122 having reached the surface of the third semiconductor layer 105 using an etching solution such as heated H₃PO₄ or HBr as an etchant, the recess 106 and the recess 107 can be formed. This type of etching processing is used for confirming the presence/absence of dislocations in semiconductor crystals and the distribution of places of occurrence, and is well known. In this technology, a recess formed at a place of a dislocation through etching processing is called an etch-pit.

Note that Br₂:CH₃OH, HBr:H₂O₂:HCl:H₂O, HNO₃:HCl:Br₂, H₃PO₄:HBr, HBr:HNO₃, HBr:HF, HBr:CH₃COOH, or the like is applicable to the etchant to be used in the case of forming the recess 106 and the recess 107 in the third semiconductor layer 105 composed of InP. Alternatively, the recesses can also be formed by etching through etching processing having crystalline anisotropy.

Examples of the etching processing for confirming threading dislocations include etching processing on a GaAs layer with molten KOH. The above-described etching processing can be carried out at lower temperatures than in the processing with molten KOH. The etching processing for confirming threading dislocations also includes a technology for forming an etch-pit using a solution called an AB etchant containing CrO₃, AgNO₃, or the like. However, this etching processing raises concern that heavy metals contained in the etching solution are introduced as impurities into a layer to be subjected to regrowth which will be described later. In contrast, such a problem does not arise in the processing with the etching solution such as heated H₃PO₄ or HBr.

The etching solution used in the above-described etching processing on the third semiconductor layer 105 composed of InP typically erodes a material containing a large amount of Al easily. Thus, the first semiconductor layer 102, if present under and in contact with the third semiconductor layer 105, will be eroded. The second semiconductor layer 103 is thus provided between the first semiconductor layer 102 and the third semiconductor layer 105 as an etching stop layer. The second semiconductor layer 103 is provided, and etching processing is performed using an etchant that selectively dissolves the third semiconductor layer 105 in contrast to the second semiconductor layer 103 to form the recess 106 and the recess 107.

In the above-described etching processing on the third semiconductor layer 105, a material containing a large amount of Al is easily eroded, and as the amount of Al contained increases, the degree of erosion increases. It is therefore important to use, for the second semiconductor layer 103, a material that is lattice-matched with the buffer layer 104 (the first semiconductor layer 102), and does not contain Al or contains Al at a low composition ratio. Candidates for the material suited to this condition include, for example, InGaAs, InGaAsP, InGaAlAs containing Al at a low composition, and the like.

Note that containing Al at a low composition ratio indicates that Al may be contained within a range in which the function as an etching stop layer is exerted in the etching processing performed when forming the recess 106 and the recess 107.

The above-described lattice matching indicates that a difference in lattice constant between an underlying layer and an overlying layer falls within such a range in which a displacement does not occur, for example, from the interface between the underlying layer and the overlying layer or the like when the overlying layer is epitaxially grown on the underlying layer. In other words, it indicates that the difference in lattice constant between the underlying layer and the overlying layer falls within a range in which a critical film thickness of the overlying layer determined by the difference in lattice constant is larger than a target thickness. Note that the lattice constant is a lattice constant in a direction parallel to the substrate plane.

An amount of etching (or etching time) for forming the recess 106 and the recess 107 is set as appropriate comprehensively considering the dislocation density, etching selectivity between the third semiconductor layer 105 and the second semiconductor layer 103, and thicknesses of the third semiconductor layer 105 and the second semiconductor layer 103.

Next, as shown in FIG. 1E, a through-hole 108 and a through-hole 109 that extend through the second semiconductor layer 103 are formed in the second semiconductor layer 103 under the places of the recess 106 and the recess 107 (fifth step). By forming the through-hole 108 and the through-hole 109, threading dislocations in the second semiconductor layer 103 are removed. In this step, an etchant that selectively dissolves the second semiconductor layer 103 in contrast to the first semiconductor layer 102 and the third semiconductor layer 105 is used. In addition, in this step, the second semiconductor layer 103 is etched using the third semiconductor layer 105 in which the recess 106 and the recess 107 have been formed as a mask through the etching processing with this etchant, thereby forming the through-hole 108 and the through-hole 109.

In the above-described etching processing, such an etching solution that contains hydrogen peroxide solution (H₂O₂), for example, can be used as the etchant. The first semiconductor layer 102 is made of a material containing a large amount of Al, and the surface is thus oxidized thinly when in touch with the above-described etching solution. This oxidized layer functions as an etching stop layer in the etching processing on the second semiconductor layer 103. When the etching solution reaches the surface of the first semiconductor layer 102 in the process of forming the through-hole 108 and the through-hole 109 in the second semiconductor layer 103 through the above-described etching processing, the oxidized layer is formed, and etching no longer progresses.

Next, the first semiconductor layer 102 is oxidized through the recess 106, the recess 107, the through-hole 108, and the through-hole 109 to form an insulation film 112 that covers a lower surface of the second semiconductor layer 103 as shown in FIG. 1F (sixth step). In the first embodiment, the first semiconductor layer 102 is entirely oxidized to form the insulation film 112 in an amorphous state. The insulation film 112 is formed by oxidizing AlAsSb to form AlOₓ by well-known steam thermal oxidation, for example.

Next, the third semiconductor layer 105 is subjected to crystal regrowth after forming the insulation film 112 to make the third semiconductor layer 105 thicker than in an initial state as shown in FIG. 1G (seventh step). Crystal regrowth can be carried out by a method such as MOVPE or HVPE method, for example. By making the third semiconductor layer 105 thicker through the crystal regrowth to fill the recess 106 and the recess 107, the surface of the third semiconductor layer 105 is made relatively flat. InP constituting the third semiconductor layer 105 is easier to flatten through crystal regrowth than a GaAs-based material.

The first embodiment allows regrowth to be performed after etching the places of dislocations in the third semiconductor layer 105 and forming recesses, and thus allows dislocations to be removed from the third semiconductor layer 105 in principle. In addition, the insulation film 112 in an amorphous state formed by oxidization is provided under the third semiconductor layer 105, so that propagation of dislocations from the layers under the insulation film 112 is prevented. In this manner, the third semiconductor layer 105 is subjected to crystal regrowth to obtain the third semiconductor layer 105 free from dislocations in the first embodiment. In other words, the third semiconductor layer 105 is a semiconductor layer composed of a target semiconductor, free from dislocations or the like, and having favorable crystallinity, as desired to be formed. InP is the target semiconductor in the first embodiment.

Herein, the relation between the hole diameter of the recess 106 and the recess 107 in the shape as seen in plan view and the density of the threading dislocation 121 and the threading dislocation 122 is important for forming the recess 106 and the recess 107. FIG. 2 shows a relation between the threading dislocation density occurred in semiconductor layers formed through crystal growth of compound semiconductors different in lattice constant in the planar direction of the surface of the grown substrate and the length (region dimension) of one side of regions having a rectangular shape as seen in plan view including one dislocation in average. This relation can be calculated by L=1/sqrt(D) where D indicates the threading dislocation density, and L indicates the region dimension. In a case where the threading dislocation density is 10⁸ cm⁻², for example, it is indicated that one threading dislocation is present within a quadrangle having a 1-μm side as seen in plan view.

In a case of forming recesses in a semiconductor layer having a threading dislocation density of 10⁸ cm⁻², for example, adjacent recesses will be coupled to each other and the semiconductor layer will be etched entirely if the diameter of the recesses as seen in plan view has a size exceeding 1 μm. This requires the diameter as seen in plan view to have a size less than or equal to a dislocation occurrence frequency (threading dislocation density) when forming the recesses.

In addition, it is important for the recess 106 and the recess 107 to extend through the third semiconductor layer 105 to reach the second semiconductor layer 103. The shape of the recess 106 and the recess 107 varies depending on the material of the third semiconductor layer 105 and the etchant to be used for forming the recess 106 and the recess 107. It is therefore necessary to previously grasp the size of the diameter as seen in plan view, depth, and the like of the recess 106 and the recess 107 to be formed. This can be carried out by observing recesses formed on trial with an optical microscope or electronic microscope.

For example, in a case of forming recesses whose ratio (aspect ratio) between the size of the diameter as seen in plan view and depth is 1, the thickness of a semiconductor layer in which the recesses are formed needs to be a thickness of less than or equal to the dislocation occurrence frequency shown in FIG. 2, and the size of the diameter of the recesses to be formed as seen in plan view needs to be less than or equal to the thickness of the semiconductor layer. In a case where the recesses are different in aspect ratio, the semiconductor layer needs to be produced with such a thickness that allows the recesses to extend through to reach an underlying layer in accordance with this ratio.

According to the above-described first embodiment, the third semiconductor layer 105 is free from threading dislocations. In addition, the threading dislocation 121 and the threading dislocation 122 occurred at the heterointerface between the substrate 101 and the buffer layer 104 do not propagate to the layers overlying the insulation film 112, so that the threading dislocations do not propagate to the third semiconductor layer 105 above the insulation film 112. In this manner, the first embodiment allows semiconductor layers to be produced with reduced dislocation density, and allows the dislocations to be prevented from rising to a desired semiconductor layer after production. In addition, the above-described first embodiment uses the crystal growth technology and recess (etch-pit) forming technology conventionally and commonly used, and allows the semiconductor layers to be produced very simply.

### Second Embodiment

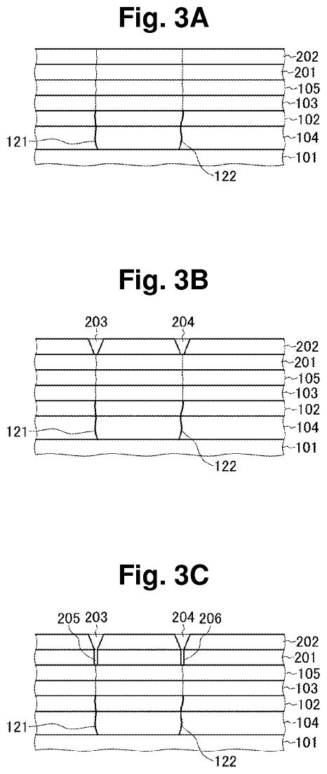

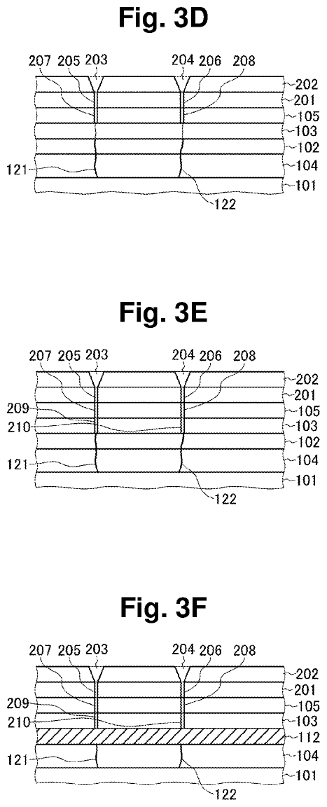

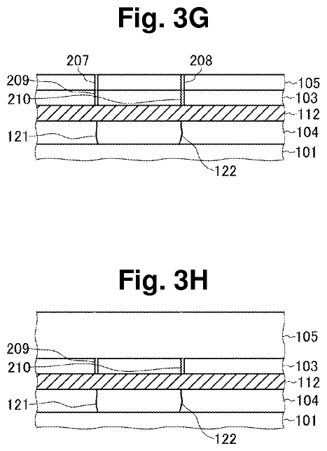

Next, a method of forming semiconductor layers according to a second embodiment of the present invention will be described with reference to FIG. 3A to FIG. 3H.

First, as shown in FIG. 3A, the first semiconductor layer 102 is formed through crystal growth above the substrate 101, the first semiconductor layer 102 being different from the substrate 101 in lattice constant in the planar direction of the surface of the substrate 101 (first step). In the second embodiment, the buffer layer 104 is formed through crystal growth on the substrate 101, and the first semiconductor layer 102 is formed through crystal growth (epitaxially grown) on the buffer layer 104. In addition, the second semiconductor layer 103 is formed through crystal growth on and in contact with the first semiconductor layer 102 (second step). In addition, the third semiconductor layer 105 is formed through crystal growth on and in contact with the second semiconductor layer 130 (third step). The substrate 101, the first semiconductor layer 102, the second semiconductor layer 103, and the third semiconductor layer 105 are similar to those of the first embodiment described earlier.

In the second embodiment, furthermore, a fourth semiconductor layer 201 is formed through crystal growth on and in contact with the third semiconductor layer 105 (fourth step), a fifth semiconductor layer 202 is formed through crystal growth on and in contact with the fourth semiconductor layer 201 (fifth step). The fourth semiconductor layer 201 is composed of a compound semiconductor such as InGaAs, for example. The fourth semiconductor layer 201 can be composed of the same material as the second semiconductor layer 103. The fifth semiconductor layer 202 is composed of a compound semiconductor such as InP, for example. The fifth semiconductor layer 202 can be composed of the same material as the third semiconductor layer 105, for example.

Also in the second embodiment, the threading dislocation 121 and the threading dislocation 122 occur at the heterointerface between the substrate 101 and the buffer layer 104, and the threading dislocation 121 and the threading dislocation 122 as occurred propagate to the surface of the first semiconductor layer 102. The threading dislocation 121 and the threading dislocation 122 propagate through the second semiconductor layer 103, the third semiconductor layer 105, and the fourth semiconductor layer 201, and further propagate to the surface of the fifth semiconductor layer 202.

Next, as shown in FIG. 3B, a recess 203 and a recess 204 are formed at places where the threading dislocation 121 and the threading dislocation 122 reach the surface of the fifth semiconductor layer 202, the recess 203 and the recess 204 extending through the fifth semiconductor layer 202 to reach the fourth semiconductor layer 201 (sixth step). By selectively dissolving the places of the threading dislocation 121 and the threading dislocation 122 having reached the surface of the fifth semiconductor layer 202 using the fourth semiconductor layer 201 as an etching stop layer, the recess 203 and the recess 204 can be formed.

By etching the places of the threading dislocation 121 and the threading dislocation 122 having reached the surface of the fifth semiconductor layer 202 using an etching solution such as heated H₃PO₄ or HBr as an etchant, for example, the recess 203 and the recess 204 can be formed. Formation of the recess 203 and the recess 204 is similar to the formation of the recess 106 and the recess 107 in the first embodiment described earlier. Also in the second embodiment, the fourth semiconductor layer 201 serves as the etching stop layer.

Next, as shown in FIG. 3C, a first through-hole 205 and a first through-hole 206 are formed in the fourth semiconductor layer 201 under the places of the recess 203 and the recess 204, the first through-hole 205 and the first through-hole 206 extending through the fourth semiconductor layer 201 (seventh step). By forming the first through-hole 205 and the first through-hole 206, threading dislocations in the fourth semiconductor layer 201 are removed. In this step, an etchant that selectively dissolves the fourth semiconductor layer 201 in contrast to the third semiconductor layer 105 and the fifth semiconductor layer 202 is used. In addition, in this step, the fourth semiconductor layer 201 is etched using the fifth semiconductor layer 202 in which the recess 203 and the recess 204 have been formed as a mask, and using the third semiconductor layer 105 as an etching stop layer in the etching processing with this etchant, thereby forming the first through-hole 205 and the first through-hole 206.

Next, as shown in FIG. 3D, a second through-hole 207 and a second through-hole 208 are formed in the third semiconductor layer 105 under the places of the first through-hole 205 and the first through-hole 206, the second through-hole 207 and the second through-hole 208 extending through the third semiconductor layer 105 (eighth step). By forming the second through-hole 207 and the second through-hole 208, threading dislocations in the third semiconductor layer 105 are removed. In this step, an etchant that selectively dissolves the third semiconductor layer 105 in contrast to the second semiconductor layer 103 and the fourth semiconductor layer 201 is used. In addition, in this step, the third semiconductor layer 105 is etched using the fifth semiconductor layer 202 in which the recess 203 and the recess 204 have been formed as a mask, and using the second semiconductor layer 103 as an etching stop layer in the etching processing with this etchant, thereby forming the second through-hole 207 and the second through-hole 208.

Next, as shown in FIG. 3E, a third through-hole 209 and a third through-hole 210 are formed in the second semiconductor layer 103 under the places of the second through-hole 207 and the second through-hole 208, the third through-hole 209 and the third through-hole 210 extending through the second semiconductor layer 103 (ninth step). By forming the third through-hole 209 and the third through-hole 210, threading dislocations in the second semiconductor layer 103 are removed. In this step, an etchant that selectively dissolves the second semiconductor layer 103 in contrast to the first semiconductor layer 102 and the third semiconductor layer 105 is used. In addition, in this step, the second semiconductor layer 103 is etched using the fifth semiconductor layer 202 in which the recess 203 and the recess 204 have been formed as a mask, and using the first semiconductor layer 102 as an etching stop layer in the etching processing with this etchant, thereby forming the third through-hole 209 and the third through-hole 210. This step is similar to the formation of the through-hole 108 and the through-hole 109 in the first embodiment described earlier.

Note that the first through-hole 205, the first through-hole 206, the second through-hole 207, the second through-hole 208, the third through-hole 209, and the third through-hole 210 can also be formed continuously. Successive etching of the fourth semiconductor layer 201, the third semiconductor layer 105, and the second semiconductor layer 103 using the fifth semiconductor layer 202 in which the recess 203 and the recess 204 have been formed as a mask through etching processing in which the first semiconductor layer 102 can be used as an etching stop layer, for example, allows the first through-hole 205, the first through-hole 206, the second through-hole 207, the second through-hole 208, the third through-hole 209, and the third through-hole 210 to be formed.

Next, the first semiconductor layer 102 is oxidized through the recess 203, the recess 204, the first through-hole 205, the first through-hole 206, the second through-hole 207, the second through-hole 208, the third through-hole 209, and the third through-hole 210 to form the insulation film 112 that covers the lower surface of the second semiconductor layer 103 as shown in FIG. 3F (tenth step). Also in the second embodiment, the insulation film 112 in an amorphous state is formed by entirely oxidizing the first semiconductor layer 102, similarly to the first embodiment described earlier.

Next, the fifth semiconductor layer 202 and the fourth semiconductor layer 201 are removed after forming the insulation film 112 (eleventh step). In the oxidization processing of the first semiconductor layer 102 as described above, phosphorus (P) constituting the fifth semiconductor layer 202 which forms the outermost surface may evaporate (what is called P evaporation), and the crystallinity may degrade. Although the oxidization rate can be increased by raising the processing temperature in the oxidization processing, for example, the above-described P evaporation may occur in such a case. Thus, the fifth semiconductor layer 202 and the fourth semiconductor layer 201 are removed to expose the surface of the third semiconductor layer 105 in which crystal degradation as described above has not occurred, as shown in FIG. 3G.

Similarly to the first embodiment described earlier, the third semiconductor layer 105 is a layer which is a semiconductor layer composed of a target semiconductor, free from dislocations or the like, and having favorable crystallinity, as desired to be formed. Also in the second embodiment, InP is the target semiconductor.

Next, the third semiconductor layer 105 is subjected to crystal regrowth to make the third semiconductor layer 105 thicker than in the initial state as shown in FIG. 3H (twelfth step). Crystal regrowth can be carried out by a method such as MOVPE or HVPE method, for example. By making the third semiconductor layer 105 thicker through the crystal regrowth to fill the recess 203 and the recess 204, the surface of the third semiconductor layer 105 is made relatively flat. InP constituting the third semiconductor layer 105 is easier to flatten through crystal regrowth than a GaAs-based material.

The second embodiment allows regrowth to be performed after etching the places of dislocations in the third semiconductor layer 105 and forming through-holes. Dislocations are thus removed from the third semiconductor layer 105 in principle. In addition, the insulation film 112 in an amorphous state formed by oxidization is provided under the third semiconductor layer 105, so that propagation of dislocations from the underlying layers is prevented.

Also in the above-described second embodiment, the third semiconductor layer 105 is free from threading dislocations similarly to the first embodiment described earlier. In addition, the threading dislocation 121 and the threading dislocation 122 occurred at the heterointerface between the substrate 101 and the buffer layer 104 do not propagate to the layers overlying the insulation film 112, so that threading dislocations do not propagate to the third semiconductor layer 105 above the insulation film 112. In this manner, the second embodiment also allows the semiconductor layer to be produced with reduced dislocation density, and allows dislocations to be prevented from rising to a desired (target) semiconductor layer after production. In addition, the above-described second embodiment also uses the crystal growth technology and recess (etch-pit) forming technology conventionally and commonly used, and allows the semiconductor layers to be produced very simply.

As described above, according to the present invention, the second semiconductor layer to serve as an etching stop layer is formed on the first semiconductor layer, and recesses that reach the second semiconductor layer are formed at places of dislocations in the third semiconductor layer formed on the second semiconductor layer. Furthermore, through-holes are formed in the second semiconductor layer, and the first semiconductor layer is oxidized through the recesses and the through-holes to form an insulation film that covers the lower surface of the second semiconductor layer. This allows semiconductor layers with reduced dislocation density to be produced by a simple production method, and allows dislocations to be prevented from rising to a desired semiconductor layer after production.

Note that it is apparent that the present invention is not limited to the embodiments described above, and many modifications and combinations can be made by those skilled in the art within the technical scope of the present invention.

### REFERENCE SIGNS LIST

101 substrate
102 first semiconductor layer
103 second semiconductor layer
104 buffer layer
105 third semiconductor layer
106 recess
107 recess
108 through-hole
109 through-hole
112 insulation film
121 threading dislocation
122 threading dislocation

1. A method of forming semiconductor layers, comprising:
a first step of forming a first semiconductor layer through crystal growth on a substrate, the first semiconductor layer being different from the substrate in lattice constant in a planar direction of a surface of the substrate;
a second step of forming a second semiconductor layer through crystal growth on and in contact with the first semiconductor layer;
a third step of forming a third semiconductor layer through crystal growth on and in contact with the second semiconductor layer;
a fourth step of selectively dissolving a place of a dislocation in the third semiconductor layer using the second semiconductor layer as an etching stop layer to form a recess at the place of the dislocation, the recess extending through the third semiconductor layer;
a fifth step of forming a through-hole in the second semiconductor layer under a place of the recess, the through-hole extending through the second semiconductor layer;
a sixth step of oxidizing the first semiconductor layer through the recess and the through-hole in the second semiconductor layer to form an insulation film that covers a lower surface of the second semiconductor layer; and
a seventh step of subjecting the third semiconductor layer to crystal regrowth after forming the insulation film.

2. A method of forming semiconductor layers, comprising:
a first step of forming a first semiconductor layer through crystal growth on a substrate, the first semiconductor layer being different from the substrate in lattice constant in a planar direction of a surface of the substrate;
a second step of forming a second semiconductor layer through crystal growth on and in contact with the first semiconductor layer;
a third step of forming a third semiconductor layer through crystal growth on and in contact with the second semiconductor layer;
a fourth step of forming a fourth semiconductor layer through crystal growth on and in contact with the third semiconductor layer;
a fifth step of forming a fifth semiconductor layer through crystal growth on and in contact with the fourth semiconductor layer;
a sixth step of dissolving a place of a dislocation in the fifth semiconductor layer to form a recess at the place of the dislocation, the recess extending through the fifth semiconductor layer;
a seventh step of forming a first through-hole in the fourth semiconductor layer under a place of the recess, the first through-hole extending through the fourth semiconductor layer;
an eighth step of forming a second through-hole in the third semiconductor layer under a place of the first through-hole through etching using the second semiconductor layer as an etching stop layer, the second through-hole extending through the third semiconductor layer;
a ninth step of forming a third through-hole in the second semiconductor layer under a place of the second through-hole, the third through-hole extending through the second semiconductor layer;
a tenth step of oxidizing the first semiconductor layer through the recess, the first through-hole, the second through-hole, and the second through-hole to form an insulation film that covers a lower surface of the second semiconductor layer;
an eleventh step of removing the fifth semiconductor layer after forming the insulation film;
a twelfth step of removing the fourth semiconductor layer after removing the fifth semiconductor layer; and
a thirteenth step of subjecting the third semiconductor layer to crystal regrowth after removing the fourth semiconductor layer.

3. The method of forming semiconductor layers according to claim 2, wherein the fourth semiconductor layer and the fifth semiconductor layer are composed of compound semiconductors.

4. The method of forming semiconductor layers according to claim 1, wherein
the first semiconductor layer is composed of a compound semiconductor containing Al, and
the second semiconductor layer and the third semiconductor layer are composed of compound semiconductors.

5. The method of forming semiconductor layers according to claim 1, wherein the recess is formed by etching through etching processing having crystalline anisotropy.

6. The method of forming semiconductor layers according to claim 1, wherein the first step includes a step of, after forming a buffer layer on the substrate, forming the first semiconductor layer through crystal growth on the buffer layer.

7. The method of forming semiconductor layers according to claim 6, wherein the buffer layer is composed of a compound semiconductor, and a lattice constant of the buffer layer in the planar direction of the surface of the substrate approaches the lattice constant of the first semiconductor layer in the planar direction of the surface of the substrate toward the first semiconductor layer.

8. The method of forming semiconductor layers according to claim 4, wherein the lattice constant of the first semiconductor layer in the planar direction of the surface of the substrate approaches the lattice constant of the second semiconductor layer in the planar direction of the surface of the substrate toward the second semiconductor layer.

9. The method of forming semiconductor layers according to claim 2, wherein
the first semiconductor layer is composed of a compound semiconductor containing Al, and
the second semiconductor layer and the third semiconductor layer are composed of compound semiconductors.

10. The method of forming semiconductor layers according to claim 3, wherein
the first semiconductor layer is composed of a compound semiconductor containing Al, and
the second semiconductor layer and the third semiconductor layer are composed of compound semiconductors.

11. The method of forming semiconductor layers according claim 2, wherein the recess is formed by etching through etching processing having crystalline anisotropy.

12. The method of forming semiconductor layers according to claim 3, wherein the recess is formed by etching through etching processing having crystalline anisotropy.

13. The method of forming semiconductor layers according to claim 4, wherein the recess is formed by etching through etching processing having crystalline anisotropy.

14. The method of forming semiconductor layers according to claim 2, wherein the first step includes a step of, after forming a buffer layer on the substrate, forming the first semiconductor layer through crystal growth on the buffer layer.

15. The method of forming semiconductor layers according to claim 3, wherein the first step includes a step of, after forming a buffer layer on the substrate, forming the first semiconductor layer through crystal growth on the buffer layer.

16. The method of forming semiconductor layers according to claim 4, wherein the first step includes a step of, after forming a buffer layer on the substrate, forming the first semiconductor layer through crystal growth on the buffer layer.
